(19) United States
(12) Patent Application Publication
(10) Pub. No.: US 2025/0040360 A1
(43) Pub. Date: Jan. 30, 2025

(54) DISPLAY DEVICE

(71) Applicant: Samsung Display Co., LTD., Yongin-si (KR)

(72) Inventors: Hee Sung YANG, Yongin-si (KR); Su Kyeong SHIN, Yongin-si (KR); Woo Jin CHO, Yongin-si (KR); Sang Gab KIM, Yongin-si (KR); Joon Hwa BAE, Yongin-si (KR)

(21) Appl. No.: 18/632,476

(22) Filed: Apr. 11, 2024

(30) Foreign Application Priority Data
Jul. 24, 2023 (KR) 10-2023-0095815

(51) Int. Cl. H10K 59/124

(52) U.S. Cl. CPC H10K 59/124

(57) ABSTRACT

A display device includes: a substrate; a thin film transistor positioned on the substrate and including a source electrode, a drain electrode, and an active layer positioned between the source electrode and the drain electrode; a gate electrode positioned on the thin film transistor and overlapping the active layer in a plan view; a gate protection layer positioned on the gate electrode and overlapping the active layer in the plan view; an insulating layer positioned on the gate protection layer; and a gate cover layer positioned between side surfaces of the gate electrode and the insulating layer, where the gate cover layer includes a first portion and a second portion spaced apart from the first portion with the gate electrode interposed therebetween, and the first portion and the second portion are in contact with the gate protection layer.

This application claims priority to Korean Patent Application No. 10-2023-0095815, filed on Jul. 24, 2023, and all the benefits accruing therefrom under 35 U.S.C. § 119, the content of which in its entirety is herein incorporated by reference.

### BACKGROUND

### 1. Technical Field

The present disclosure relates to a display device.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices. Among such flat panel display devices, a light emitting display device may display an image without a backlight unit providing light to a display panel because each of pixels of the display panel includes light emitting elements that may emit light by themselves.

### SUMMARY

Aspects of the present disclosure provide a display device including low-resistance lines capable of high-resolution and high-speed driving.

Aspects of the present disclosure also provide a method of manufacturing a display device in which a thickness of a gate electrode is increased.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

In an embodiment of the disclosure, a display device includes: a substrate; a thin film transistor positioned on the substrate and including a source electrode, a drain electrode, and an active layer positioned between the source electrode and the drain electrode; a gate electrode positioned on the thin film transistor and overlapping the active layer in a plan view; a gate protection layer positioned on the gate electrode and overlapping the active layer in the plan view; an insulating layer positioned on the gate protection layer; and a gate cover layer positioned between side surfaces of the gate electrode and the insulating layer, wherein the gate cover layer includes a first portion and a second portion spaced apart from the first portion with the gate electrode interposed therebetween, and the first portion and the second portion are in contact with the gate protection layer.

In an embodiment, the gate protection layer may include a first surface facing the insulating layer, the first portion includes a second surface facing the insulating layer, and the first surface and the second surface are aligned with each other in a direction parallel to a major surface of the substrate.

In an embodiment, the second portion may include a third surface facing the insulating layer, and the first surface may be positioned between the second surface and the third surface.

In an embodiment, the first surface, the second surface, and the third surface may be aligned with each other in the direction parallel to the substrate.

In an embodiment, the first surface, the second surface, and the third surface may be in contact with the insulating layer.

In an embodiment, the gate electrode may include a lower surface facing the substrate, and an inclination angle formed between the side surface of the gate electrode and the lower surface of the gate electrode is equal to or greater than 60° and less than 90°.

In an embodiment, a thickness of the gate electrode may be about 0.5 micrometers (μm) or more.

In an embodiment, a thickness of the gate cover layer may be equal to or greater than about 0.05 μm and equal to or less than about 0.25 μm.

In an embodiment, the gate cover layer may surround an entirety of the gate protection layer in the plan view.

In an embodiment, the first portion and the second portion may be monolithic in the plan view.

In an embodiment, an entirety of the gate protection layer may be surrounded by the gate electrode, the gate cover layer, and the insulating layer.

In an embodiment, the side surface of the gate electrode may be in contact with the gate cover layer.

In an embodiment, the gate protection layer may cover the side surface of the gate electrode, and the gate protection layer is in contact with the side surface of the gate electrode.

In an embodiment, the display device may further comprise a buffer layer positioned between the thin film transistor and the gate electrode, wherein an entirety of the gate electrode may be surrounded by the buffer layer and the gate protection layer.

In an embodiment, the gate cover layer may be not in contact with the gate electrode.

In an embodiment, the gate protection layer may include a metal oxide and an inorganic insulating film.

In an embodiment of the disclosure, a display device includes: a substrate; a thin film transistor positioned on the substrate and including a source electrode, a drain electrode, and an active layer positioned between the source electrode and the drain electrode; a gate electrode positioned on the thin film transistor and overlapping the active layer in a plan view; an insulating layer positioned on the gate electrode; and a gate cover layer positioned between side surfaces of the gate electrode and the insulating layer, where the gate cover layer includes a first portion and a second portion and exposes an upper surface of the gate electrode, and the second portion is spaced apart from the first portion, the first portion includes a first surface facing the insulating layer, and the upper surface of the gate electrode and the first surface of the first portion are aligned with each other in a direction parallel to a major surface of the substrate.

In an embodiment, the second portion may include a second surface facing the insulating layer, and the upper surface of the gate electrode may be positioned between the first surface and the second surface.

In an embodiment, the upper surface of the gate electrode and the first surface and the second surface of the gate cover layer may be in contact with the insulating layer.

In an embodiment, an entirety of the gate electrode may be surrounded by the gate cover layer in the plan view.

In a display device according to an embodiment, it is possible to provide low-resistance lines capable of high-resolution and high-speed driving by increasing a thickness of a gate electrode.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a plan view illustrating a display panel according to an embodiment;

FIG. 3 is a cross-sectional view of the display device taken along line Y1-Y1′ of FIG. 1;

FIG. 4 is a schematic plan view illustrating the display panel of FIG. 3;

FIG. 5 is a plan view illustrating an arrangement of emission areas in a display area of FIG. 4;

FIG. 6 is a cross-sectional view of the display panel taken along line X1-X1′ of FIG. 5;

FIG. 7 is an enlarged cross-sectional view of area ‘A’ of FIG. 6;

FIG. 8 is an enlarged cross-sectional view of area ‘C’ of FIG. 7;

FIG. 9 is a schematic enlarged plan view of area ‘C’ of FIG. 7;

FIG. 10 is an enlarged cross-sectional view of area ‘C’ of FIG. 7 according to another embodiment;

FIG. 11 is an enlarged cross-sectional view of area ‘C’ of FIG. 7 according to still another embodiment;

FIG. 12 is a cross-sectional view of a display device taken along line X1-X1′ of FIG. 5 according to another embodiment;

FIG. 13 is an enlarged cross-sectional view of area ‘T’ of FIG. 12; and

FIG. 14 is a schematic enlarged plan view of area ‘T’ of FIG. 12.

### DETAILED DESCRIPTION

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, illustrative embodiments will be described with reference to the accompanying drawings.

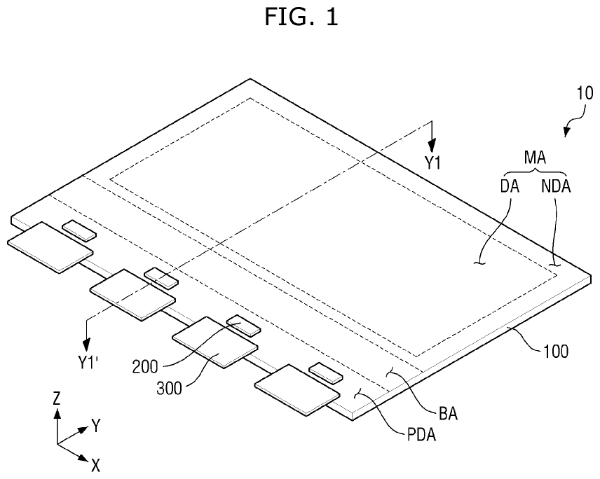

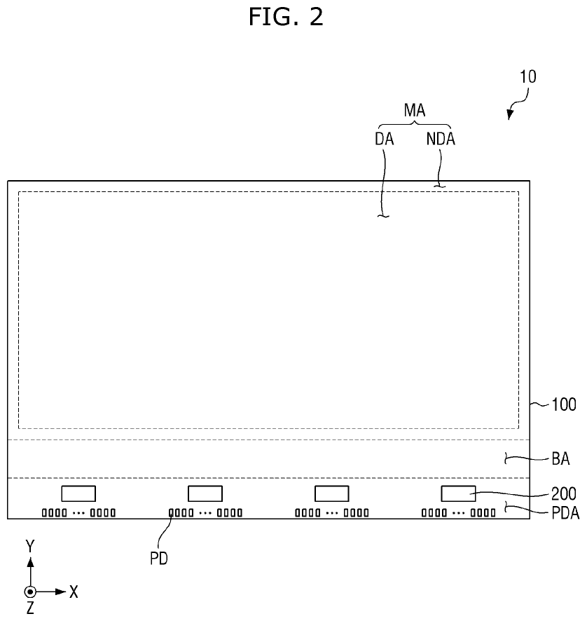

FIG. 1 is a perspective view illustrating a display device according to an embodiment. FIG. 2 is a plan view illustrating a display panel according to an embodiment. As used herein, the “plan view” is a view in a third direction (Z-axis direction).

Referring to FIGS. 1 and 2, a display device 10 according to an embodiment is a device that displays a moving image or a still image, and may be used as a display screen of various products such as televisions, laptop computers, monitors, billboards, and the Internet of Things (“IoT”) devices as well as portable electronic devices such as mobile phones, smartphones, tablet personal computers (“PCs”), smart watches, watch phones, mobile communication terminals, electronic notebooks, electronic books, portable multimedia players (“PMPs”), navigation devices, and ultra mobile PCs (“UMPCs”).

The display device 10 according to an embodiment may be a light emitting display device such as an organic light emitting display device using organic light emitting diodes, a quantum dot light emitting display device including quantum dot light emitting layers, an inorganic light emitting display device including inorganic semiconductors, and a micro light emitting display device using micro or nano light emitting diodes (micro LEDs or nano LEDs). Hereinafter, it will be mainly described that the display device 10 is the organic light emitting display, but the present disclosure is not limited thereto.

The display device 10 according to an embodiment may include a display panel 100, display drivers 200, and circuit boards 300.

The display panel 100 may have a rectangular shape, in a plan view, having long sides in a first direction (X-axis direction) and short sides in a second direction (Y-axis direction) crossing the first direction (X-axis direction). A corner where the long side in the first direction (X-axis direction) and the short side in the second direction (Y-axis direction) meet may be right-angled or rounded with a curvature. The shape of the display panel 100 in a plan view is not limited to the rectangular shape, and may be other polygonal shapes, a circular shape, or an elliptical shape. In the drawings, the first direction (X-axis direction) and the second direction (Y-axis direction) are horizontal directions, respectively, and cross each other. For example, the first direction (X-axis direction) and the second direction (Y-axis direction) may be orthogonal to each other. In addition, a third direction (Z-axis direction) may be a perpendicular direction crossing, for example, orthogonal to, the first direction (X-axis direction) and the second direction (Y-axis direction). In the present disclosure, directions indicated by arrows of the first to third directions (X-axis direction, Y-axis direction, and Z-axis direction) may be referred to as one side, and directions opposite to the one side may be referred to as the other side.

The display panel 100 may be formed to be flat, but is not limited thereto. For another example, the display panel 100 may include curved surface portions formed at left and right ends thereof and having a constant curvature or a variable curvature. In addition, the display panel 100 may be flexibly formed to be curved, bent, folded, or rolled.

The display panel 100 may include a main area MA, a bending area BA, and a pad area PDA. The main area MA may include a display area DA displaying an image and a non-display area NDA disposed around the display area DA.

The display area DA may occupy most of the area of the display panel 100. The display area DA may be disposed at the center of the display panel 100. Pixels each including a plurality of emission areas in order to display an image may be disposed in the display area DA.

The non-display area NDA may be disposed to neighbor to the display area DA. The non-display area NDA may be an area outside the display area DA. The non-display area NDA may be disposed to surround the display area DA. The non-display area NDA may be an edge area of the display panel 100.

The bending area BA may be disposed between the main area MA and the pad area PA in the second direction (Y-axis direction). The bending area BA may be an area bent below the display panel 100. When the bending area BA is bent below the display panel 100, a plurality of display drivers 200 and circuit boards 300 may be disposed below the display panel 100.

The pad area PDA may be a lower edge area of the display panel 100. The pad area PDA may include the display drivers 200, display pads PD, and the circuit boards 300.

The display drivers 200 may be disposed in the pad area PDA. Each of the display drivers 200 may be attached to the non-display area NDA of the display panel 100 in a chip on glass (“COG”) manner. In another embodiment, each of the display drivers 200 may also be attached to the circuit board 300 in a chip on plastic (“COP”) manner.

The circuit boards 300 may be disposed on the display pads PD disposed on an edge of one side of the display panel 100. The circuit boards 300 may be attached to the display pads PD using a conductive adhesive member such as an anisotropic conductive film and an anisotropic conductive adhesive. Accordingly, the circuit boards 300 may be electrically connected to signal lines of the display panel 100. Each of the circuit boards 300 may be a flexible printed circuit board or a flexible film such as a chip on film.

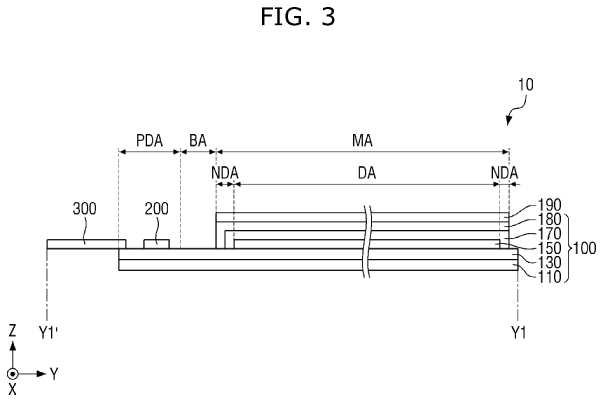

FIG. 3 is a cross-sectional view of the display device taken along line Y1-Y1′ of FIG. 1.

Referring to FIG. 3, the display device 10 may include the display panel 100, a color filter layer 190, the display driver 200, and the circuit board 300. The display panel 100 may include a substrate 110, a thin film transistor layer 130, a display element layer 150, a thin film encapsulation layer 170, and a touch sensor layer 180.

The substrate 110 may be a base substrate or a base member. The substrate 110 may be a flexible substrate that may be bent, folded, and rolled. As an example, the substrate 110 may include a polymer resin such as polyimide (“PI”), but is not limited thereto. As another example, the substrate 110 may include a glass material or a metal material.

The thin film transistor layer 130 may be disposed on the substrate 110. The thin film transistor layer 130 may include a plurality of thin film transistors. The thin film transistor may include a semiconductor region, a source electrode, a drain electrode, and a gate electrode. In addition, the thin film transistor layer 130 may further include gate lines, data lines, power lines, gate control lines, fan-out lines connecting the display driver 200 and the data lines to each other, and lead lines connecting the display driver 200 and pad parts to each other. For example, when a gate driver is disposed on one side of the non-display area NDA of the display panel 100, the gate driver may include thin film transistors.

The thin film transistor layer 130 may be disposed in the main area MA, the bending area BA, and the pad area PDA. The thin film transistors, the gate lines, the data lines, and the power lines of the thin film transistor layer 130 may be disposed in the display area DA of the main area MA, and the gate control lines and the fan-out lines of the thin film transistor layer 130 may be disposed in the non-display area NDA of the main area MA. In addition, the lead lines of the thin film transistor layer 130 may be disposed in the bending area BA and the pad area PDA.

The display element layer 150 may be disposed on the thin film transistor layer 130. The display element layer 150 may include a plurality of light emitting elements each including a pixel electrode, a light emitting layer, and a common electrode to emit light, a pixel defining layer, a bank structure, and the like.

In an embodiment, the light emitting layer may be an organic light emitting layer including an organic material. The light emitting layer may include a hole transporting layer, an organic light emitting layer, and an electron transporting layer. When the pixel electrode receives a voltage through the thin film transistor of the thin film transistor layer 130 and the common electrode receives a cathode voltage, holes and electrons may move to the organic light emitting layer through the hole transporting layer and the electron transporting layer, respectively, and may be combined with each other in the organic light emitting layer to emit light. In another embodiment, the light emitting element may include a quantum dot light emitting diode including a quantum dot light emitting layer, an inorganic light emitting diode including an inorganic semiconductor, or a micro light emitting diode.

The thin film encapsulation layer 170 may cover an upper surface and side surfaces of the display element layer 150, and may protect the display element layer 150. The thin film encapsulation layer 170 may include at least one inorganic film and at least one organic film for encapsulating the display element layer 150.

The touch sensor layer 180 may be disposed on the thin film encapsulation layer 170. The touch sensor layer 180 may include a plurality of touch electrodes for sensing a user's touch in a capacitance manner and a plurality of touch lines. For example, the touch sensor layer 180 may sense the user's touch in a mutual capacitance manner or a self-capacitance manner.

The color filter layer 190 may be disposed on the thin film encapsulation layer 170. The color filter layer 190 may include a plurality of color filters each corresponding to the plurality of emission areas. Each of the color filters may selectively transmit light of a specific wavelength therethrough and block or absorb light of other wavelengths. The color filter layer 190 may absorb some of light introduced from the outside of the display device 10 to reduce reflected light by external light. Accordingly, the color filter layer 190 may prevent distortion of colors due to external light reflection.

Since the color filter layer 190 is directly disposed on the thin film encapsulation layer 170, the display device 10 may not require a separate substrate for the color filter layer 190.

Although not illustrated in the drawings, the pad area PDA of the display device 10 may be bent by the bending area BA. When the pad area PDA is bent by the bending area BA, the display driver 200 and the circuit board 300 positioned in the pad area PDA may overlap the main area MA in the third direction (Z-axis direction).

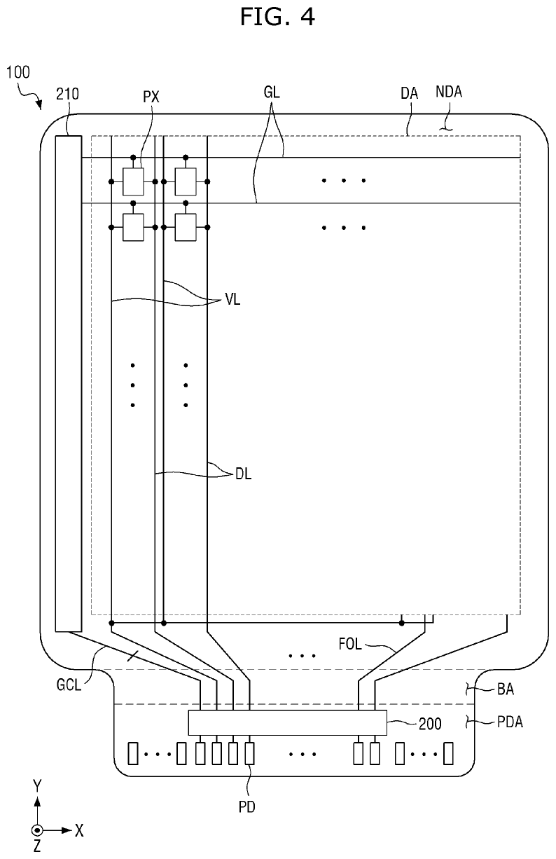

FIG. 4 is a schematic plan view illustrating the display panel of FIG. 3.

Referring to FIG. 4, a plurality of pixels PX, a plurality of gate lines GL, a plurality of data lines DL, and a plurality of power lines VL may be disposed in the display area DA of the display panel 100. Each of the plurality of pixels PX may be defined as a minimum unit emitting light.

The plurality of gate lines GL may supply gate signals received from a gate driver 210 to the plurality of pixels PX. The plurality of gate lines GL may extend in the first direction X, and may be spaced apart from each other in the second direction Y crossing the first direction X.

The plurality of data lines DL may supply data voltages received from the display driver 200 to the plurality of pixels PX. The plurality of data lines DL may extend in the second direction Y, and may be spaced apart from each other in the first direction X.

The plurality of power lines VL may supply a source voltage received from the display driver 200 to the plurality of pixels PX. Here, the source voltage may be at least one of a driving voltage, an initialization voltage, a reference voltage, and a low potential voltage. The plurality of power lines VL may extend in the second direction Y, and may be spaced apart from each other in the first direction X.

The gate driver 210, fan-out lines FOL, and gate control lines GCL may be disposed in the non-display area NDA of the display panel 100.

The gate driver 210 may generate a plurality of gate signals based on gate control signals, and may sequentially supply the plurality of gate signals to the plurality of gate lines GL according to a set order.

The fan-out lines FOL may extend from the display driver 200 to the display area DA. The fan-out lines FOL may supply the data voltages received from the display driver 200 to the plurality of data lines DL.

The gate control lines GCL may extend from the display driver 200 to the gate driver 210. The gate control lines GCL may supply the gate control signals received from the display driver 200 to the gate driver 210.

The pad area PDA of the display panel 100 may include the display driver 200 and a plurality of display pads PD.

The display driver 200 may output signals and voltages for driving the display panel 100 to the fan-out lines FOL. The display driver 200 may supply the data voltages to the data lines DL through the fan-out lines FOL. The data voltages may be supplied to the plurality of pixels PX, and may control luminance of the plurality of pixels PX. The display driver 200 may supply the gate control signals to the gate driver 210 through the gate control lines GCL.

The plurality of display pads PD may be connected to a graphic system through the circuit board 300. The plurality of display pads PD may be connected to the circuit board 300 to receive digital video data, and may supply the digital video data to the display driver 200.

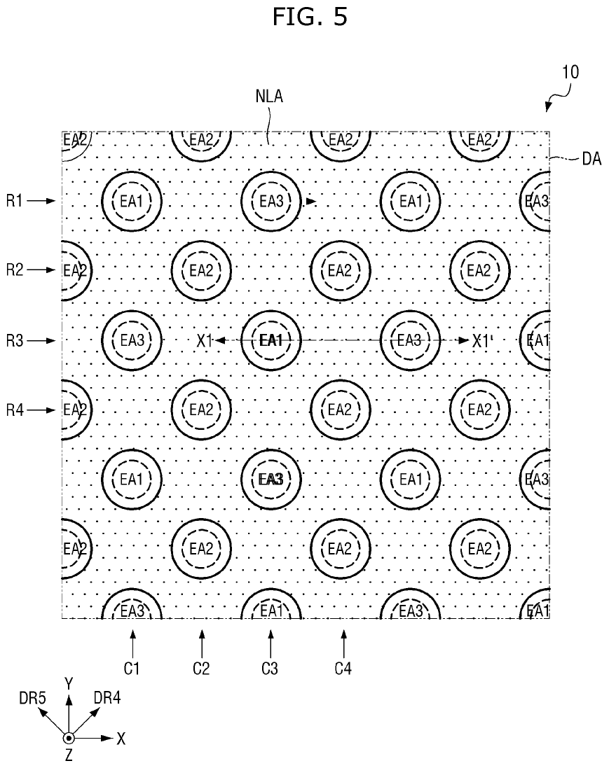

FIG. 5 is a plan view illustrating an arrangement of emission areas EA1, EA2, and EA3 in the display area DA of FIG. 4.

Referring to FIG. 5, the display device 10 may include a plurality of emission areas EA1, EA2, and EA3 and a non-emission area NLA disposed in the display area DA.

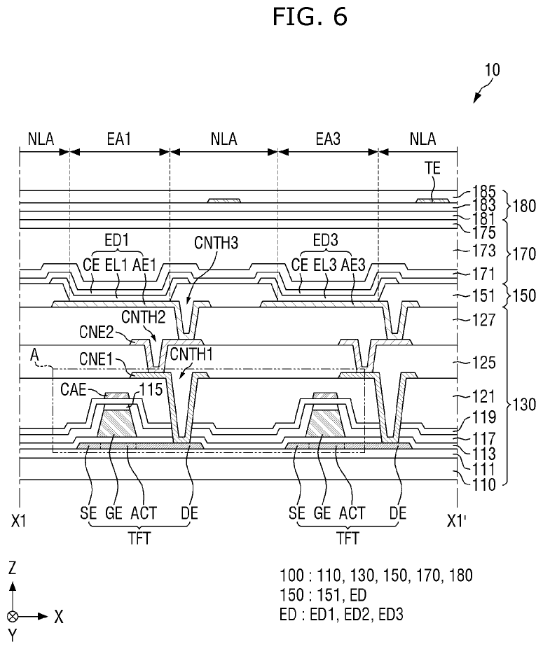

The emission areas EA1, EA2, and EA3 may include first emission areas EA1, second emission areas EA2, and third emission areas EA3 that emit light of different colors. The plurality of emission areas EA1, EA2, and EA3 may emit red, green, or blue light, respectively, and colors of the light emitted from the respective emission areas EA1, EA2, and EA3 may be different from each other depending on types of light emitting elements ED (see FIG. 6) to be described later. In an embodiment, the first emission area EA1 may emit first light, which is the red light, the second emission area EA2 may emit second light, which is the green light, and the third emission area EA3 may emit third light, which is the blue light. However, the present disclosure is not limited thereto.

The plurality of emission areas EA1, EA2, and EA3 may be disposed in a PenTile™ type, for example, a diamond PenTile™ type. For example, the first emission areas EA1 and the third emission areas EA3 may be disposed to be spaced apart from each other in the first direction X, and may be alternately disposed in the first direction X and the second direction Y. In an arrangement of the emission areas EA1, EA2, and EA3, the first emission areas EA1 and the third emission areas EA3 may be alternately disposed in the first direction X in a first row R1 and a third row R3. The first emission areas EA1 and the third emission areas EA3 may be alternately disposed in the second direction Y in a first column C1 and a third column C3.

The second emission areas EA2 may be spaced apart from other adjacent second emission areas EA2 in the first direction X and the second direction Y, and may be spaced apart from adjacent first emission areas EA1 and third emission areas EA3 in a fourth direction DR4 or a fifth direction DR5. A plurality of second emission areas EA2 may be repeatedly disposed along the first direction X and the second direction Y, and the second emission areas EA2 and the first emission areas EA1 or the second emission areas EA2 and the third emission areas EA3 may be alternately disposed along the fourth direction DR4 or the fifth direction DR5. In the arrangement of the emission areas EA1, EA2, and EA3, the second emission areas EA2 may be repeatedly disposed in the first direction X in a second row R2 and a fourth row R4, and the second emission areas EA2 may be repeatedly disposed in the second direction Y in a second column C2 and a fourth column C4.

Each of the plurality of emission areas EA1, EA2, and EA3 may be defined by a pixel defining layer 151 (see FIG. 6) to be described later.

The non-emission area NLA may be positioned while surrounding the emission areas EA1, EA2, and EA3. The non-emission area NLA may be an area in which light is not emitted. A pixel defining layer 151 to be described later may be positioned in the non-emission area NLA.

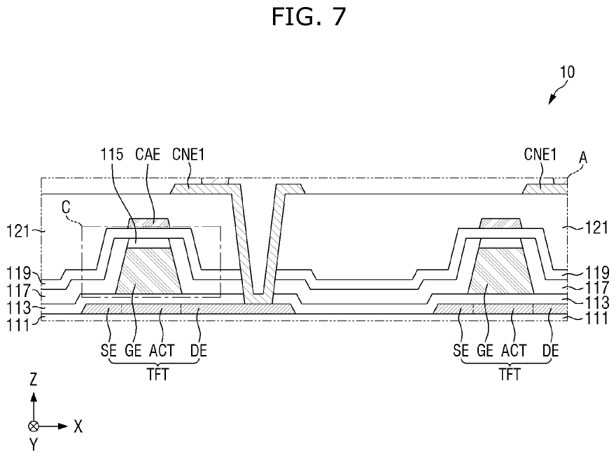

FIG. 6 is a cross-sectional view of the display panel taken along line X1-X1′ of FIG. 5. FIG. 7 is an enlarged cross-sectional view of area ‘A’ of FIG. 6.

Referring to FIG. 6, the display panel 100 may include the substrate 110, the thin film transistor layer 130, the display element layer 150, the thin film encapsulation layer 170, and the touch sensor layer 180.

The substrate 110 has already been described above, and a description thereof will thus be omitted.

The thin film transistor layer 130 may include a first buffer layer 111, thin film transistors TFT, a first insulating layer 113, a gate protection layer 115, a gate cover layer 117, a second insulating layer 119, a third insulating layer 121, first connection electrodes CNE1, a first passivation layer 125, second connection electrodes CNE2, and a second passivation layer 127.

The first buffer layer 111 may be disposed on the substrate 110. The first buffer layer 111 may include an inorganic film capable of preventing permeation of air or moisture. For example, the first buffer layer 111 may include a plurality of inorganic films that are alternately stacked.

The thin film transistor TFT may be disposed on the first buffer layer 111, and may constitute a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE. The semiconductor layer ACT may overlap the gate electrode GE in a third direction (Z-axis direction), and may be insulated from the gate electrode GE by the first insulating layer 113. The semiconductor layer ACT may be referred to as “active layer” and be disposed between the source electrode SE and the drain electrode DE. The first insulating layer 113 may be referred to as “a second buffer layer”. A material of the semiconductor layer ACT in portions of the semiconductor layer ACT may become conductors to form the source electrode SE and the drain electrode DE. The semiconductor layer ACT may include polycrystalline silicon, but is not limited thereto. For another example, the semiconductor layer ACT may include amorphous silicon or the like.

The first insulating layer 113 may be disposed on the semiconductor layer ACT. For example, the first insulating layer 113 may cover the semiconductor layer ACT, the source electrode SE, the drain electrode DE, and the first buffer layer 111, and may insulate the semiconductor layer ACT and the gate electrode GE from each other. The first insulating layer 113 may be disposed at substantially the same thickness along a profile of the thin film transistor TFT. That is, a distance (thickness) between the closest two surfaces of the first insulating layer 113, facing each other, at each location is substantially the same. The first insulating layer 113 may include an inorganic insulating material, and may be formed as a plurality of layers. As an example, the first insulating layer 113 may be configured as a single layer made of silicon nitride (SiNₓ) or silicon oxide (SiOₓ) or multiple layers made of silicon nitride (SiNₓ) and silicon oxide (SiOₓ). The first insulating layer 113 may define first contact holes CNTH1 through which the first connection electrodes CNE1 penetrate.

Referring to FIGS. 6 and 7, the gate electrode GE may be disposed on the first insulating layer 113. The gate electrode GE may overlap the semiconductor layer ACT with the first insulating layer 113 interposed therebetween in the third direction.

The gate electrode GE may include a metal. For example, the gate electrode GE may include one or more metals selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu).

The gate protection layer 115 may be disposed on the gate electrode GE. The gate protection layer 115 may serve to protect an upper surface of the gate electrode GE so that the upper surface of the gate electrode GE is not polished by a chemical mechanical polishing process in a manufacturing process of the display device 10.

The gate protection layer 115 may include a transparent conductive material or an inorganic insulating film, and all metal layers constituting lines of the display device 10. As an example, the gate protection layer 115 may include all of indium tin oxide (ITO), indium zinc oxide (IZO), silicon nitride (SiNₓ) or silicon oxide (SiOₓ), aluminum (Al), aluminum alloys, molybdenum (Mo), molybdenum alloys, copper (Cu), copper alloys, titanium (Ti), titanium alloys, molybdenum titanium alloys (MoTi), and the like. In another embodiment, the gate protection layer 115 may be omitted.

The gate cover layer 117 may be disposed on the gate electrode GE and the first insulating layer 113. The gate cover layer 117 may be positioned to cover an upper surface of the first insulating layer 113 and side surfaces of the gate electrode GE, and may expose the gate protection layer 115 in the first direction (X-axis direction). The gate cover layer 117 may define first contact holes CNTH1 through which the first connection electrodes CNE1 penetrate.

The gate cover layer 117 may be positioned between side surfaces of the gate electrode GE and a second insulating layer 119 to be described later to alleviate a step that the second insulating layer 119 should cover. In other words, the gate cover layer 117 may serve to decrease a profile that the second insulating layer 119 should cover.

The gate cover layer 117 may include an inorganic insulating material, and may be formed as a plurality of layers. As an example, the gate cover layer 117 may be configured as a single layer made of silicon nitride (SiNₓ) or silicon oxide (SiOₓ) or multiple layers made of silicon nitride (SiNₓ) and silicon oxide (SiOₓ).

The second insulating layer 119 may be disposed on the gate protection layer 115 and the gate cover layer 117. The second insulating layer 119 may be disposed at substantially the same thickness along profiles of the gate cover layer 117 and the gate electrode GE. That is, a distance (thickness) between the closest two surfaces of the second insulating layer 119, facing each other, at each location is substantially the same. The second insulating layer 119 may include the same material as the first insulating layer 113.

Capacitor electrodes CAE may be disposed on the second insulating layer 119. The capacitor electrode CAE may overlap the gate electrode GE of the thin film transistor T in the third direction (Z-axis direction). Since the second insulating layer 119 has a predetermined dielectric constant, a capacitor may be formed by the capacitor electrode CAE, the gate electrode G, and the second insulating layer 119 disposed between the capacitor electrode CAE and the gate electrode G. The second insulating layer 119 may define first contact holes CNTH1 through which the first connection electrodes CNE1 penetrate.

The capacitor electrode CAE may include a metal. As an example, the capacitor electrode CAE may include one or more metals selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu).

The third insulating layer 121 may be disposed on the second insulating layer 119 and the capacitor electrodes CAE. The third insulating layer 121 may cover the second insulating layer 119 and the capacitor electrodes CAE. The third insulating layer 121 may define first contact holes CNTH1 through which the first connection electrodes CNE1 penetrate. The first contact holes CNTH1 penetrating through the third insulating layer 121, the second insulating layer 119, the gate cover layer 117, and the first insulating layer 113 may extend.

The first connection electrodes CNE1 may be disposed on the third insulating layer 121. The first connection electrode CNE1 may electrically connect the drain electrode DE of the thin film transistor TFT and the second connection electrode CNE2 to each other. The first connection electrode CNE1 may be inserted into the first contact holes CNTH1 defined in the third insulating layer 121, the second insulating layer 119, the gate cover layer 117, and the first insulating layer 113 to be in contact with the drain electrode DE of the thin film transistor TFT.

The first passivation layer 125 may cover the first connection electrodes CNE1 and the third insulating layer 121. The first passivation layer 125 may protect the thin film transistors TFT. The first passivation layer 125 may define second contact holes CNTH2 through which the second connection electrodes CNE2 penetrate.

The second connection electrodes CNE2 may be disposed on the first passivation layer 125. The second connection electrodes CNE2 may electrically connect the first connection electrodes CNE1 and pixel electrodes AE1, AE2, and AE3 of light emitting elements ED to each other. The second connection electrode CNE2 may be in contact with the first connection electrode CNE1 through the second contact hole CNTH2 defined in the first passivation layer 125.

The second passivation layer 127 may cover the second connection electrodes CNE2 and the first passivation layer 125. The second passivation layer 127 may define third contact holes CNTH3 through which the pixel electrodes AE1, AE2, and AE3 of the light emitting elements ED penetrate.

The display element layer 150 may be disposed on the thin film transistor layer 130. The display element layer 150 may include light emitting elements ED and a pixel defining layer 151. The light emitting elements ED may include a first light emitting element ED1, a second light emitting element ED2, and a third light emitting element ED3 that overlap the emission areas EA1, EA2, and EA3, respectively. Specifically, the first light emitting element ED1 may overlap the first emission area EA1, the second light emitting element ED2 may overlap the second emission area EA2, and the third light emitting element ED3 may overlap the third emission area EA3. In addition, the first light emitting element ED1 may include a first pixel electrode AE1, a first light emitting layer EL1, and a common electrode CE, the second light emitting element ED2 may include a second pixel electrode AE2, a second light emitting layer EL2, and a common electrode CE, and the third light emitting element ED3 may include a third pixel electrode AE3, a third light emitting layer EL3, and a common electrode CE.

In FIG. 6, for convenience of explanation, the first light emitting element ED1 and the third light emitting element ED3 have been illustrated and described, but the second light emitting element ED2 may also have the same structure and characteristics as the first light emitting element ED1 and the third light emitting element ED3.

The pixel electrodes AE1, AE2, and AE3 may be disposed on the second passivation layer 127 so as to overlap the emission areas EA1, EA2, and EA3, respectively. The pixel electrodes AE1, AE2, and AE3 may be disposed to overlap openings defined by the pixel defining layer 151 in the third direction. The pixel electrodes AE1, AE2, and AE3 may be electrically connected to the drain electrodes DE of the thin film transistors TFT through the first connection electrodes CNE1 and the second connection electrodes CNE2.

The pixel defining layer 151 may be positioned to overlap the non-emission area NLA. The pixel defining layer 151 may be disposed on the second passivation layer 127 and portions of the pixel electrodes AE1, AE2, and AE3. The pixel defining layer 151 may define the openings, and the emission areas EA1, EA2, and EA3 of the display device 10 may be defined by the openings defined by the pixel defining layer 151.

The pixel defining layer 151 may include a light absorbing material to prevent light reflection. As an example, the pixel defining layer 151 may include a polyimide (PI)-based binder and a mixture of red, green and blue pigments or include a cardo-based binder resin, a mixture of lactam-based black pigment and blue pigment, and carbon black.

The light emitting layers EL1, EL2, and EL3 may be positioned on the pixel electrodes AE1, AE2, and AE3, respectively. The light emitting layers EL1, EL2, and EL3 may be organic light emitting layers made of an organic material. In a case where the light emitting layers EL1, EL2, and EL3 correspond to the organic light emitting layers, when the thin film transistors TFT apply predetermined voltages to the pixel electrodes AE1, AE2, and AE3 of the light emitting elements ED1, ED2, and ED3 and the common electrode CE of the light emitting elements ED1, ED2, and ED3 receives a common voltage or a cathode voltage, holes and electrons may move to the light emitting layers EL1, EL2, and EL3 through hole transporting layers and electron transporting layers, respectively, and may be combined with each other in the light emitting layers EL1, EL2, and EL3 to emit light.

The common electrode CE may be disposed on the light emitting layers EL1, EL2, and EL3 and the pixel defining layer 151. The common electrode CE is not divided for each of the plurality of pixels, and may be disposed on the entire surface of the display area DA in the form of an electrode common to all pixels.

The common electrode CE may receive the common voltage or a low potential voltage. When the pixel electrodes AE1, AE2, and AE3 receive voltages corresponding to data voltages and the common electrode C receives the low potential voltage, potential differences are formed between the pixel electrodes AE1, AE2, and AE3 and the common electrode CE, such that the light emitting layers EL1, EL2, and EL3 may emit the light.

The thin film encapsulation layer 170 may be disposed on the common electrode CE to cover a plurality of light emitting elements ED1, ED2, and ED3. The thin film encapsulation layer 170 may include at least one inorganic film and at least one organic film to prevent oxygen, moisture, or foreign substances such as dust from permeating into the display element layer 150.

The thin film encapsulation layer 170 may include a first encapsulation layer 171, a second encapsulation layer 173, and a third encapsulation layer 175 that are sequentially stacked in the third direction (Z-axis direction). The first encapsulation layer 171 and the third encapsulation layer 175 may be inorganic layers, and the second encapsulation layer 173 disposed between the first encapsulation layer 171 and the third encapsulation layer 175 may be an organic layer.

Each of the first encapsulation layer 171 and the third encapsulation layer 175 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer 173 may include a polymer-based material. The polymer-based material may include an acrylic resin, an epoxy-based resin, polyimide, polyethylene, and the like. For example, the second encapsulation layer 173 may include an acrylic resin such as polymethyl methacrylate or polyacrylic acid. The second encapsulation layer 173 may be formed by curing a monomer or applying a polymer.

The touch sensor layer 180 may be disposed on the thin film encapsulation layer 170. The touch sensor layer 180 may include a touch buffer layer 181, a touch insulating layer 183, touch electrodes TE, and a touch protection layer 185.

The touch buffer layer 181 may be disposed on the thin film encapsulation layer 170. The touch buffer layer 181 may have insulating and optical functions. The touch buffer layer 181 may include at least one inorganic film. Optionally, the touch buffer layer 181 may be omitted. Although not illustrated in the drawings, a connection electrode may be disposed on the touch buffer layer 181. The connection electrode may electrically connect the touch electrodes to each other.

The touch insulating layer 183 may be disposed on the touch buffer layer 181. The touch insulating layer 183 may have an insulating function. For example, the touch insulating layer 183 may be an inorganic film including at least one of a silicon nitride (SiN) layer, a silicon oxynitride (SiON) layer, a silicon oxide (SiO₂) layer, a titanium oxide (TiO₂) layer, and an aluminum oxide (AlO₃) layer.

The touch electrodes TE may be disposed on the touch insulating layer 183 so as to overlap the non-emission area NLA. Each of the touch electrodes TE may not overlap the first to third emission areas EA1, EA2, and EA3.

The touch electrode TE may include a conductive metal. As an example, the touch electrode TE may be formed as a single layer made of molybdenum (Mo), titanium (Ti), copper (Cu), aluminum (Al), or indium tin oxide (“ITO”) or be formed as a stacked structure (Ti/Al/Ti) of aluminum and titanium, a stacked structure (ITO/AI/ITO) of aluminum and ITO, an Ag—Pd—Cu (APC) alloy, and a stacked structure (ITO/APC/ITO) of an APC alloy and ITO.

The touch protection layer 185 may cover the touch electrodes TE and the touch insulating layer 183. The touch protection layer 185 may have insulating and optical functions. The touch protection layer 185 may be made of the material exemplified in the touch insulating layer 183.

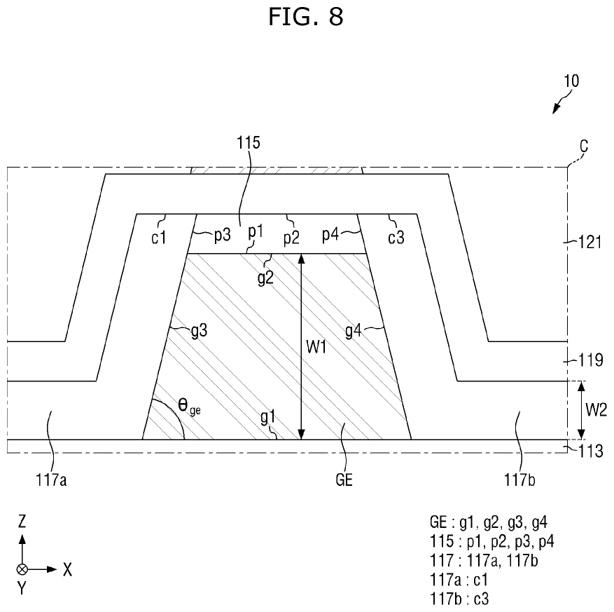

FIG. 8 is an enlarged cross-sectional view of area ‘C’ of FIG. 7.

Referring to FIG. 8, the gate electrode GE of the display device 10 may be positioned on the first insulating layer 113, and may include a lower surface g1, an upper surface g2, and a first side surface g3, and a second side surface g4. The lower surface g1 of the gate electrode GE may be a surface in contact with the first insulating layer 113, and the upper surface g2 of the gate electrode GE may be a surface opposing the lower surface g1. The upper surface g2 and the lower surface g1 of the gate electrode GE may be connected to each other by the first side surface g3 and the second side surface g4. A width of the upper surface g2 of the gate electrode GE may be smaller than a width of the lower surface g1 of the gate electrode GE, and the gate electrode GE may have a trapezoidal shape, but is not limited thereto.

The first side surface g3 and the second side surface g4 of the gate electrode GE may be inclined surfaces. A first inclination angle θ_{ge} formed between the lower surface g1 of the gate electrode GE and the first side surface g3 of the gate electrode GE may be an acute angle. As an example, the first inclination angle θ_{ge} may be about 60° or more, specifically, equal to or greater than about 60° and less than 90°. A thickness W1 of the gate electrode GE in the third direction (Z-axis direction) may be about 0.5 micrometers (μm) or more.

The gate protection layer 115 may be positioned to be in contact with the upper surface g2 of the gate electrode GE. The gate protection layer 115 may include a lower surface p1 in contact with the gate electrode GE, an upper surface p2, a first side surface p3, and a second side surface p4. The upper surface p2 of the gate protection layer 115 may be one surface opposing the lower surface p1 of the gate protection layer 115, and the first side surface p3 and the second side surface p4 of the gate protection layer 115 may connect the upper surface p2 and the lower surface p1 of the gate protection layer 115 to each other. In some embodiments, the first side surface g3 of the gate electrode GE and the first side surface p3 of the gate protection layer 115 may extend while being aligned with each other, but are not limited thereto.

An entirety of the gate protection layer 115 according to the present embodiment may be surrounded by the gate electrode GE, the gate cover layer 117, and the second insulating layer 119.

In some embodiments, one surface of the gate cover layer 117 may selectively polished using a chemical mechanical polishing (“CMP”) device that performs a chemical mechanical polishing process in the manufacturing process of the display device 10. The gate protection layer 115 may serve to protect the gate electrode GE so that the gate electrode GE is not polished. In addition, the gate protection layer 115 may also serve to protect the gate electrode GE so that the gate electrode GE is not corroded due to chemicals included in the CMP device. As an example, the chemicals included in the CMP device may include CeOₓ, AlOₓ, SiOₓ, Zirconia, and the like, and may not include H₂O₂.

The gate cover layer 117 may be positioned on opposite side surfaces of the gate electrode GE and opposite side surfaces of the gate protection layer 115. The gate cover layer 117 may prevent a defect caused by a step of the gate electrodes GE. As described above, the gate electrode GE may have the thickness W1 of about 0.5 μm or more in the third direction (Z-axis direction) and the first inclination angle θ_{ge} of about 60° or more, specifically, equal to or greater than about 60° and less than 90°. That is, the gate electrode GE according to the present embodiment may have a structure including a high taper angle.

In general, when the second insulating layer 119 is directly disposed on the gate electrode GE without the gate cover layer 117, a portion of the gate electrode GE including the high taper angle may not be covered and may be exposed due to step coverage characteristics of the second insulating layer 119. Accordingly, the gate electrode GE whose portion is not covered by the second insulating layer 119 and is exposed may cause various defects in subsequent photolithography and etching processes.

The gate cover layer 117 of the display device 10 according to the present embodiment may be positioned between the gate electrode GE and the second insulating layer 119, and may serve to decrease the step of the gate electrode GE covered by the second insulating layer 119. Accordingly, the display according to an embodiment may include a high taper angle and a high thickness of the gate electrode GE in the third direction (Z-axis direction). Accordingly, the display according to an embodiment may provide high resolution and low resistance lines.

The gate cover layer 117 may be formed to entirely cover the gate electrode GE and the gate protection layer 115 in the manufacturing process, and a portion of the gate cover layer 117 positioned on the upper surface p2 of the gate protection layer 115 may then be entirely removed through a subsequent chemical mechanical polishing process. Accordingly, the gate cover layer 117 may be positioned only on opposite side surfaces of the gate electrode GE and the gate protection layer 115. In other words, a portion of the gate cover layer 117 positioned on the upper surface p2 of the gate protection layer 115 is removed, and thus, the gate cover layer 117 may decrease a step of a lower structure that the second insulating layer 119 should cover. For this reason, the second insulating layer 119 may cover entireties of the gate electrode GE and the gate cover layer 117. A thickness W2 of the gate cover layer 117 may be equal to or greater than about 0.05 μm and equal to or less than about 0.25 μm.

In some embodiments, the chemical mechanical polishing process for removing a portion of the gate cover layer 117 positioned on the upper surface p2 of the gate protection layer 115 may be performed once or may be performed multiple times in a manner of dividing and polishing the same thickness applied to the chemical mechanical polishing process performed once in small amounts.

As illustrated in FIG. 8, the gate cover layer 117 may include a first portion 117a and a second portion 117b. The first portion 117a of the gate cover layer 117 may be positioned on the first side surface g3 of the gate electrode GE and the first side surface p3 of the gate protection layer 115. The first portion 117a of the gate cover layer 117 may be in contact with and cover the first side surface g3 of the gate electrode GE and the first side surface p3 of the gate protection layer 115.

The second portion 117b of the gate cover layer 117 may be positioned on the second side surface g4 of the gate electrode GE and the second side surface p4 of the gate protection layer 115. The second portion 117b of the gate cover layer 117 may be in contact with and cover the second side surface g4 of the gate electrode GE and the second side surface p4 of the gate protection layer 115.

The first portion 117a of the gate cover layer 117 may be disposed to be spaced apart from the second portion 117b of the gate cover layer 117 with the gate electrode GE interposed therebetween. In other words, the first portion 117a and the second portion 117b of the gate cover layer 117 may be disposed to be spaced apart from each other with the gate electrode GE and the gate protection layer 115 interposed therebetween.

The first portion 117a of the gate cover layer 117 may include a first surface cl in a direction toward the second insulating layer 119, and the second portion 117b of the gate cover layer 117 may include a second surface c3 in the direction toward the second insulating layer 119. The first surface cl and the second surface c3 may be formed by removing a portion of the gate cover layer 117 positioned on the upper surface p2 of the gate protection layer 115. The first surface cl and the second surface c3 of the gate cover layer 117 may be positioned to be spaced apart from each other with the upper surface p2 of the gate protection layer 115 interposed therebetween, and may extend while being aligned with the upper surface p2 of the gate protection layer 115. In other words, the first surface cl and the second surface c3 of the gate cover layer 117 and the upper surface p2 of the gate protection layer 115 may be positioned on the same line (e.g., parallel to a major surface of the substrate 110, which is defined by X-axis direction and Y-axis direction).

An entirety of the second insulating layer 119 may cover the gate protection layer 115 and the gate cover layer 117. The second insulating layer 119 may be positioned to be in contact with the gate protection layer 115 and the gate cover layer 117. Specifically, the second insulating layer 119 may be positioned to be in contact with the first surface cl and the second surface c3 of the gate cover layer 117 and the upper surface p2 of the gate protection layer 115. The second insulating layer 119 may be formed at the same thickness along a profile formed by the gate cover layer 117. That is, a distance (thickness) between the closest two surfaces of the second insulating layer 119, facing each other, at each location is the same. A profile included in the second insulating layer 119 may be planarized by the third insulating layer 121.

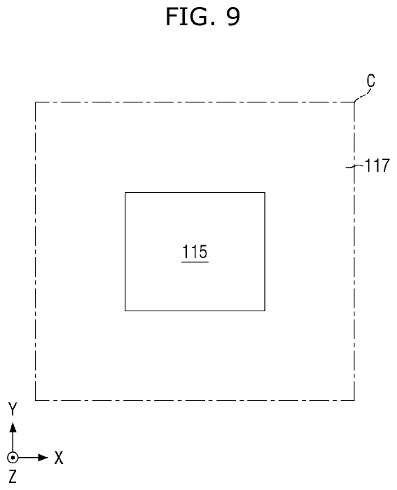

FIG. 9 is a schematic enlarged plan view of area ‘C’ of FIG. 7.

Referring to FIG. 9, an entirety of the gate protection layer 115 may be surrounded by the gate cover layer 117 in a plan view. The first portion 117a and the second portion 117b of the gate cover layer 117 are positioned to be spaced apart from each other in cross section, but may be integrally formed (i.e., monolithic) in a plan view.

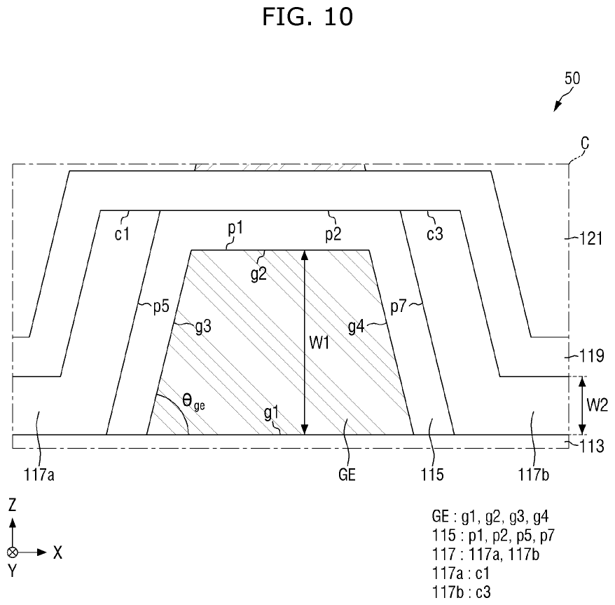

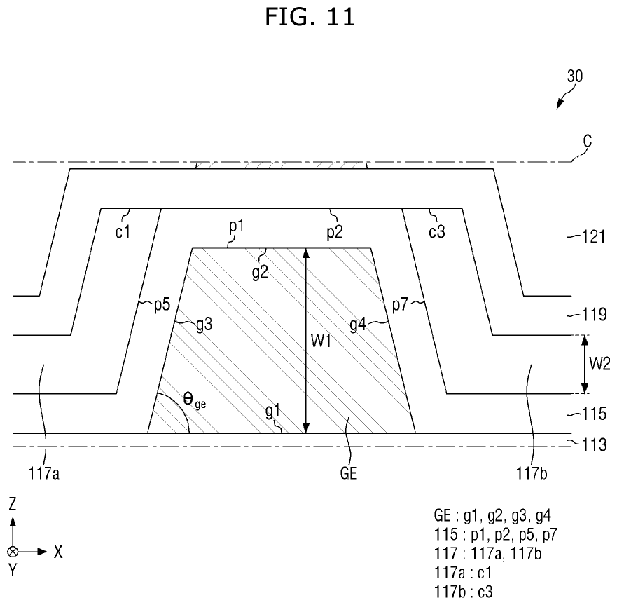

FIGS. 10 and 11 are enlarged cross-sectional views of area ‘C’ of FIG. 7 according to other embodiments.

Referring to FIGS. 10 and 11, a display device 30 and a display device 50 included in the present embodiment are different from the display device 10 according to the above-described embodiment in that the gate protection layer 115 covers opposite side surfaces of the gate electrode GE.

The gate electrode GE of each of the display device 30 and the display device 50 may be positioned on the first insulating layer 113, and may include an upper surface g2, a lower surface g1, and a first side surface g3, and a second side surface g4. The gate electrode GE may have a thickness W1 of about 0.5 μm or more in the third direction (Z-axis direction) and a first inclination angle θ_{ge} of about 60° or more, specifically, equal to or greater than about 60° and less than 90°. Other overlapping descriptions will be omitted.

The gate protection layer 115 of each of the display device 30 and the display device 50 may be positioned on the gate electrode GE. An entirety of the gate protection layer 115 of each of the display device 30 and the display device 50 may cover the gate electrode GE. The gate protection layer 115 of each of the display device 30 and the display device 50 may cover the gate electrode GE at the same thickness along a profile of the gate electrode GE. That is, a distance (thickness) between the closest two surfaces of the gate protection layer 115, facing each other, at each location is the same. Specifically, the gate protection layer 115 may be positioned to be in contact with the first side surface g3, the upper surface g2, and the second side surface g4 of the gate electrode GE.

In some embodiments, an entirety of the gate electrode GE of each of the display device 30 and the display device 50 may be surrounded by the gate protection layer 115 and the first insulating layer 113.

The gate protection layer 115 of each of the display device 30 and the display device 50 may include a lower surface p1, an upper surface p2, a first side surface p5, and a second side surface p7. The lower surface p1 of the gate protection layer 115 may be positioned to be in contact with the upper surface g2 of the gate electrode GE, and the upper surface p2 of the gate protection layer 115 may be a surface opposing the lower surface p1. The first side surface p5 of the gate protection layer 115 may be positioned on the first side surface g3 of the gate electrode GE, and the second side surface p7 of the gate protection layer 115 may be positioned on the second side surface g4 of the gate electrode GE.

Referring to FIG. 10, the gate protection layer 115 of the display device 30 may extend while covering the first insulating layer 113 in portions overlapping the outside of the gate electrode GE in the third direction. In other words, the gate protection layer 115 of the display device 30 may cover the first insulating layer 113 while extending to the other side in the first direction (X-axis direction) in a portion overlapping the outside of the gate electrode GE in the third direction. In addition, the gate protection layer 115 of the display device 30 may cover the first insulating layer 113 while extending to one side in the first direction (X-axis direction) in a portion overlapping the outside of the gate electrode GE in the third direction. In other words, an entirety of the gate electrode GE may be surrounded by the first insulating layer 113 and gate protection layer 115.

In some embodiments, the gate cover layer 117 of the display device 30 may include a first portion 117a and a second portion 117b spaced apart from each other with the gate electrode GE interposed therebetween. The first portion 117a of the gate cover layer 117 may be positioned on the first side surface p5 of the gate protection layer 115. The first portion 117a of the gate cover layer 117 may be in contact with the first side surface p5 of the gate protection layer 115. In addition, the first portion 117a of the gate cover layer 117 may extend while covering the gate protection layer 115 in the portion overlapping the outside of the gate electrode GE in the third direction. In other words, the gate protection layer 115 may be positioned between the first insulating layer 113 and the first portion 117a of the gate cover layer 117 in the portion overlapping the outside of the gate electrode GE in the third direction, and the first portion 117a of the gate cover layer 117 may be positioned between the gate protection layer 115 and the second insulating layer 119 in the portion overlapping the outside of the electrode GE.

The second portion 117b of the gate cover layer 117 may be positioned on the second side surface p7 of the gate protection layer 115. The second portion 117b of the gate cover layer 117 may be in contact with the second side surface p7 of the gate protection layer 115. In addition, the second portion 117b of the gate cover layer 117 may extend while covering the gate protection layer 115 in the portion overlapping the outside of the gate electrode GE in the third direction. In other words, the gate protection layer 115 may be positioned between the first insulating layer 113 and the second portion 117b of the gate cover layer 117 in the portion overlapping the outside of the gate electrode GE in the third direction, and the second portion 117b of the gate cover layer 117 may be positioned between the gate protection layer 115 and the second insulating layer 119 in the portion overlapping the outside of the electrode GE.

The first portion 117a of the gate cover layer 117 may include a first surface cl facing the second insulating layer 119, and the second portion 117b of the gate cover layer 117 may include a second surface c3 facing the second insulating layer 119. The first surface cl and the second surface c3 of the gate cover layer 117 may be positioned to be spaced apart from each other with the upper surface p2 of the gate protection layer 115 interposed therebetween, and the first surface cl and the second surface c3 of the gate cover layer 117 and the upper surface p2 of the gate protection layer 115 may be disposed on the same line. Other overlapping descriptions will be omitted.

The second insulating layer 119 of the display device 30 may be positioned on the gate protection layer 115 and the gate cover layer 117, and may cover entireties of the gate protection layer 115 and the gate cover layer 117. The first surface cl and the second surface c3 of the gate cover layer 117 may be in contact with the second insulating layer 119.

In some embodiments, the gate cover layer 117 of the display device 30 may surround an entirety of the gate protection layer 115 of the display device 30 in a plan view. An arrangement relationship between the gate cover layer 117 and the gate protection layer 115 of the display device 30 in a plan view may be the same as that illustrated in FIG. 9. That is, the first portion 117a and the second portion 117b of the gate cover layer 117 are positioned to be spaced apart from each other in cross section, but may be integrally formed (i.e., monolithic) in a plan view.

Referring to FIG. 11, the gate protection layer 115 of the display device 50 may be positioned on the first side surface g3 and the second side surface g4 of the gate electrode GE, and may not cover the upper surface of the first insulating layer 113 in the portions overlapping the outside of the gate electrode GE in the third direction. Accordingly, the gate protection layer 115 may not be positioned between the first insulating layer 113 and the second insulating layer 119 in the portions overlapping the outside of the gate electrode GE of the display device 50 in the third direction. In other words, the gate cover layer 117 may be positioned between the first insulating layer 113 and the second insulating layer 119.

The gate cover layer 117 of the display device 50 may be positioned on the first side surface p5 and the second side surface p7 of the gate protection layer 115. The gate cover layer 117 may include a first portion 117a positioned on the first side surface p5 of the gate protection layer 115 and a second portion 117b positioned on the second side surface p7 of the gate protection layer 115. The first portion 117a and the second portion 117b of the gate cover layer 117 may be positioned to be spaced apart from each other with the gate electrode GE interposed therebetween. In other words, the first portion 117a and the second portion 117b of the gate cover layer 117 may be positioned to be spaced apart from each other with the gate protection layer 115 interposed therebetween.

The first portion 117a of the gate cover layer 117 may include a first surface cl facing the second insulating layer 119, and the second portion 117b of the gate cover layer 117 may include a second surface c3 facing the second insulating layer 119. The first surface cl and the second surface c3 of the gate cover layer 117 may be positioned to be spaced apart from each other with the upper surface p2 of the gate protection layer 115 interposed therebetween, and the first surface cl and the second surface c3 of the gate cover layer 117 and the upper surface p2 of the gate protection layer 115 may extend on the same line. Other overlapping descriptions will be omitted.

In some embodiments, the gate cover layer 117 of the display device 50 may surround an entirety of the gate protection layer 115 of the display device 50 in a plan view. An arrangement relationship between the gate cover layer 117 and the gate protection layer 115 of the display device 50 in a plan view may be the same as that illustrated in FIG. 9. That is, the first portion 117a and the second portion 117b of the gate cover layer 117 are positioned to be spaced apart from each other in cross section, but may be integrally formed (i.e., monolithic) in a plan view.

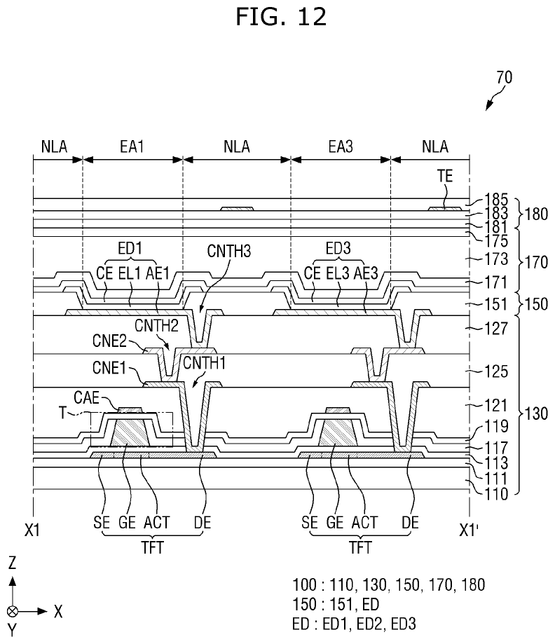

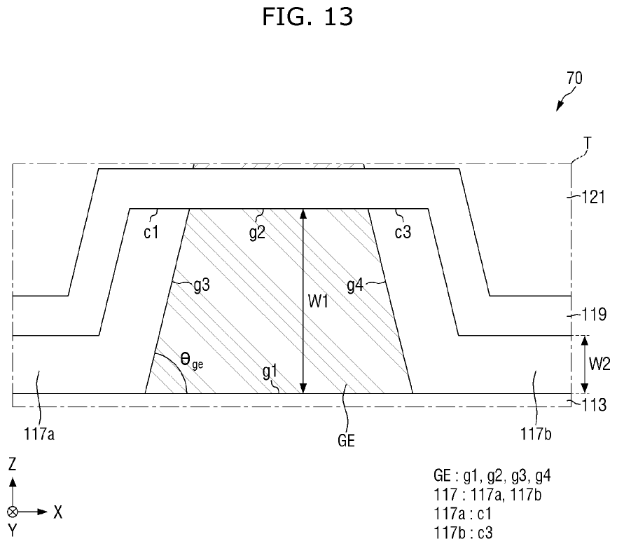

FIG. 12 is a cross-sectional view of a display device taken along line X1-X1′ of FIG. 5 according to another embodiment. FIG. 13 is an enlarged cross-sectional view of area ‘T’ of FIG. 12.

Referring to FIGS. 12 and 13, a display device 70 is different from the display devices according to the above-described embodiments in that it does not include the gate protection layer 115 on the gate electrode GE.

The gate electrode GE of the display device 70 may be positioned on the first insulating layer 113, and the gate cover layer 117 may be positioned on opposite side surfaces of the gate electrode GE. The second insulating layer 119 may be positioned on the gate electrode GE and the gate cover layer 117, and may cover an entirety of the gate electrode GE and the gate cover layer 117. Accordingly, an entirety of the gate electrode GE of the display device 70 may be surrounded by the gate cover layer 117, the first insulating layer 113, and the second insulating layer 119.

The gate electrode GE of the display device 70 may include an upper surface g2, a lower surface g1, a first side surface g3, and a second side surface g4. In addition, the gate electrode GE may have a thickness W1 of about 0.5 μm or more in the third direction (Z-axis direction) and a first inclination angle θ_{ge} of about 60° or more, specifically, equal to or greater than about 60° and less than 90°. Other overlapping descriptions will be omitted.

The gate cover layer 117 of the display device 70 may be positioned on the first side surface g3 and the second side surface g4 of the gate electrode GE. The gate cover layer 117 of the display device 70 may be formed while covering an upper surface of the gate electrode GE, and a portion of the gate cover layer 117 positioned on the upper surface of the gate electrode GE may then be entirely removed through a chemical mechanical polishing process in a manufacturing process. A thickness W2 of the gate cover layer 117 of the display device 70 may be equal to or greater than about 0.05 μm and equal to or less than about 0.25 μm.

As illustrated in FIG. 13, the gate cover layer 117 may include a first portion 117a and a second portion 117b spaced apart from each other with the gate electrode GE interposed therebetween. The first portion 117a of the gate cover layer 117 may be positioned on the first side surface g3 of the gate electrode GE. The first portion 117a of the gate cover layer 117 may be in contact with the first side surface g3 of the gate electrode GE. In addition, the first portion 117a of the gate cover layer 117 of the display device 70 may extend while covering the first insulating layer 113 in a portion overlapping the outside of the gate electrode GE in the third direction. In other words, the first portion 117a of the gate cover layer 117 may be positioned between the first insulating layer 113 and the second insulating layer 119 in the portion overlapping the outside of the gate electrode GE in the third direction.

The second portion 117b of the gate cover layer 117 may be positioned on the second side surface g4 of the gate electrode GE. The second portion 117b of the gate cover layer 117 may be in contact with the second side surface g4 of the gate electrode GE. The second portion 117b of the gate cover layer 117 may extend while covering the first insulating layer 113 in a portion overlapping the outside of the gate electrode GE in the third direction. In addition, the second portion 117b of the gate cover layer 117 may extend while covering the first insulating layer 113 in the portion overlapping the outside of the gate electrode GE in the third direction. In other words, the second portion 117b of the gate cover layer 117 may be positioned between the first insulating layer 113 and the second insulating layer 119 in the portion overlapping the outside of the gate electrode GE in the third direction.

The first portion 117a of the gate cover layer 117 according to the present embodiment may include a first surface cl toward the second insulating layer 119, and the second portion 117b of the gate cover layer 117 may include a second surface c3 toward the second insulating layer 119. The first surface cl and the second surface c3 of the gate cover layer 117 may be positioned to be spaced apart from each other with the upper surface g2 of the gate electrode GE interposed therebetween. In addition, the first surface cl and the second surface c3 of the gate cover layer 117 may be aligned with the upper surface g2 of the gate electrode GE and be positioned on the same line as the upper surface g2 of the gate electrode GE.

The second insulating layer 119 of the display device 70 may be positioned on the gate electrode GE and the gate cover layer 117, and may cover entireties of the gate electrode GE and the gate cover layer 117. The first surface cl and the second surface c3 of the gate cover layer 117 may be in contact with the second insulating layer 119.

In some embodiments, the second insulating layer 119 of the display device 70 may cover the gate cover layer 117 along a profile of the gate cover layer 117. Accordingly, a step of the gate electrode GE of the display device 70 may be decreased by the gate cover layer 117. For this reason, even though the gate electrode GE of the display device 70 has the thickness W1 of about 0.5 μm or more in the third direction (Z-axis direction) and the first inclination angle θ_{ge} of about 60° or more, specifically, equal to or greater than about 60° and less than 90°, the second insulating layer 119 of the display device 70 may cover an entirety of the gate electrode GE.

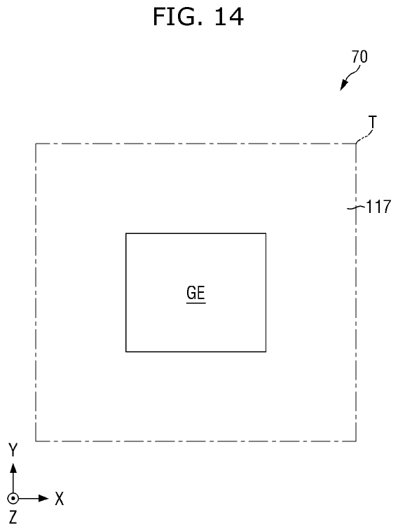

FIG. 14 is a schematic enlarged plan view of area ‘T’ of FIG. 12.

Referring to FIG. 14, an entirety of the gate electrode GE of the display device 70 may be surrounded by the gate cover layer 117 in a plan view. The first portion 117a and the second portion 117b of the gate cover layer 117 are positioned to be spaced apart from each other in cross section, but may be integrally formed (i.e., monolithic) in a plan view.

However, the effects of the disclosure are not restricted to the one set forth herein. The above and other effects of the disclosure will become more apparent to one of daily skill in the art to which the disclosure pertains by referencing the claims.

What is claimed is:

1. A display device comprising:
a substrate;
a thin film transistor positioned on the substrate and including a source electrode, a drain electrode, and an active layer positioned between the source electrode and the drain electrode;
a gate electrode positioned on the thin film transistor and overlapping the active layer in a plan view;
a gate protection layer positioned on the gate electrode and overlapping the active layer in the plan view;
an insulating layer positioned on the gate protection layer; and
a gate cover layer positioned between side surfaces of the gate electrode and the insulating layer,
wherein the gate cover layer includes a first portion and a second portion spaced apart from the first portion with the gate electrode interposed therebetween, and
the first portion and the second portion are in contact with the gate protection layer.

2. The display device of claim 1, wherein the gate protection layer includes a first surface facing the insulating layer,
the first portion includes a second surface facing the insulating layer, and
the first surface and the second surface are aligned with each other in a direction parallel to a major surface of the substrate.

3. The display device of claim 2, wherein the second portion includes a third surface facing the insulating layer, and
the first surface is positioned between the second surface and the third surface.

4. The display device of claim 3, wherein the first surface, the second surface, and the third surface are aligned with each other in the direction parallel to the substrate.

5. The display device of claim 4, wherein the first surface, the second surface, and the third surface are in contact with the insulating layer.

6. The display device of claim 1, wherein the gate electrode includes a lower surface facing the substrate, and
an inclination angle formed between the side surface of the gate electrode and the lower surface of the gate electrode is equal to or greater than about 60° and less than 90°.

7. The display device of claim 6, wherein a thickness of the gate electrode is about 0.5 micrometers (μm) or more.

8. The display device of claim 7, wherein a thickness of the gate cover layer is equal to or greater than about 0.05 μm and equal to or less than about 0.25 μm.

9. The display device of claim 1, wherein the gate cover layer surrounds an entirety of the gate protection layer in the plan view.

10. The display device of claim 9, wherein the first portion and the second portion are monolithic in the plan view.

11. The display device of claim 6, wherein an entirety of the gate protection layer is surrounded by the gate electrode, the gate cover layer, and the insulating layer.

12. The display device of claim 11, wherein the side surface of the gate electrode is in contact with the gate cover layer.

13. The display device of claim 6, wherein the gate protection layer covers the side surface of the gate electrode, and
the gate protection layer is in contact with the side surface of the gate electrode.

14. The display device of claim 13, further comprising a buffer layer positioned between the thin film transistor and the gate electrode,
wherein an entirety of the gate electrode is surrounded by the buffer layer and the gate protection layer.

15. The display device of claim 14, wherein the gate cover layer is not in contact with the gate electrode.

16. The display device of claim 1, wherein the gate protection layer includes a metal oxide and an inorganic insulating film.

17. A display device comprising:
a substrate;
a thin film transistor positioned on the substrate and including a source electrode, a drain electrode, and an active layer positioned between the source electrode and the drain electrode;
a gate electrode positioned on the thin film transistor and overlapping the active layer in a plan view;
an insulating layer positioned on the gate electrode; and
a gate cover layer positioned between side surfaces of the gate electrode and the insulating layer,
wherein the gate cover layer includes a first portion and a second portion and exposes an upper surface of the gate electrode, and the second portion is spaced apart from the first portion,
the first portion includes a first surface facing the insulating layer, and
the upper surface of the gate electrode and the first surface of the first portion are aligned with each other in a direction parallel to a major surface of the substrate.

18. The display device of claim 17, wherein the second portion includes a second surface facing the insulating layer, and
the upper surface of the gate electrode is positioned between the first surface and the second surface.

19. The display device of claim 18, wherein the upper surface of the gate electrode and the first surface and the second surface of the gate cover layer are in contact with the insulating layer.

20. The display device of claim 19, wherein an entirety of the gate electrode is surrounded by the gate cover layer in the plan view.
